(19) United States
(12) Patent Application Publication
(10) Pub. No.: US 2010/0037950 A1
(43) Pub. Date: Feb. 18, 2010

(54) Method For The Production Of Mechanically Prestressed Solar Cell Composites And Also A Mechanically Prestressed Solar Cell Module

(75) Inventor: Harry Wirth, Merzhausen (DE)

Correspondence Address: GIBSON & DERNIER LLP, 900 ROUTE 9 NORTH, SUITE 504, WOODBRIDGE, NJ, 07095, US

(73) Assignee: FRAUNHOFER-GESELLSCHAFT zur Forderung der angewandten Forschung e.V., Munchen (DE)

(21) Appl. No.: 12/535,285

(22) Filed: Aug. 4, 2009

(30) Foreign Application Priority Data
Aug. 14, 2008 (DE) 102008037821.6

(51) Int. Cl. H01L 31/00; H01L 31/18

(52) U.S. Cl. 136/256; 438/57; 257/E21.211

(57) ABSTRACT

The present invention relates to a method for the production of a solar cell composite which has a solar cell which is applied on a substrate and/or is covered by a superstrate, the substrate and/or the superstrate being connected to the solar cell via a fixing. The substrate and/or superstrate thereby has a higher thermal coefficient of expansion than the solar cell, higher process temperatures being applied during the production method before the fixing of the solar cell on the substrate and/or the superstrate. After curing of the fixing and cooling to room temperature, the solar cell is under tangential pressure which emanates from the substrate and/or superstrate and is transmitted to the solar cell by the fixing, which pressure endows the entire solar cell composite with significantly increased stability.

The present invention relates to a method for the production of a solar cell composite which has a solar cell which is applied on a substrate and/or is covered by a superstrate, the substrate and/or the superstrate being connected to the solar cell via a fixing. The substrate and/or superstrate thereby has a higher thermal coefficient of expansion than the solar cell, higher process temperatures being applied during the production method before the fixing of the solar cell on the substrate and/or the superstrate. After curing of the fixing and cooling to room temperature, the solar cell is under tangential pressure which emanates from the substrate and/or superstrate and is transmitted to the solar cell by the fixing, which pressure endows the entire solar cell composite with significantly increased stability.

Solar cells are manufactured predominantly on silicon wafers which, as brittle fracturing material, display very low strength relative to tensile loads. The strength relative to pressure loads in contrast is significantly higher.

Solar cells on a wafer basis must therefore be encapsulated for protection against external influences. Glass is used inter alia as external layer. In the case of very thin cells (<150 μm), current layer constructions lead to critical tensile loads of the cells.

According to the state of the art, wafer-based solar cells are embedded in encapsulation materials of approx. 500 μm thickness on both sides. Elastomers or thermoplasts are used as materials in order to reduce the stresses based on different thermal coefficients of expansion and based on a module deflection. These materials have a visco-elastic deformability for this purpose (e.g. EP 1 225 642).

Whilst in this technology with cell thicknesses up to approx. 150 μm and current load scenarios the solar cells are not loaded up to their failure limit, in the case of cell thicknesses below 150 μm this becomes critical. These thin cells are appearing however increasingly on the market.

It was therefore the object of the present invention to provide a method for the production of a solar cell module, via which solar cell modules with high mechanical stability are available. It was likewise the object of the present invention to indicate corresponding solar cell modules.

This object is achieved with respect to the method with the features of patent claim 1 and also with respect to the solar cell module with the feature of patent claim 9. The respective dependent claims thereby represent advantageous developments.

According to the invention, a method for the production of a solar cell module which comprises the following steps is hence indicated:
a) applying a precursor material at least in regions on at least one of the contact faces of a solar cell, a surface of a substrate and/or of a superstrate,
b) joining the contact faces together,
c) heating the substrate, the superstrate, the solar cell and/or the precursor material to a processing temperature of at least 90° C.,
d) curing the precursor material in order to fix the solar cell to the substrate and/or the superstrate, and
e) cooling the composite to ambient temperature,
   the thermal coefficient of expansion of the substrate and/or superstrate being greater than the thermal coefficient of expansion of the solar cell so that the solar cell is under tangential pressure permanently or durably for the lifespan of the solar cell module, said pressure emanating from the substrate and/or superstrate and being transmitted to the solar cell via the fixing. Steps a), b) and c) can thereby be implemented also in reverse sequence. It is crucial that the precursor material has not yet cured to form the fixing when the individual components are joined together.

According to the invention, it is hence provided that, according to the embodiment of the method according to the invention, a curable precursor material is applied on at least one contact face (i.e. at least one surface of the respective solar cell which is intended to be joined together with the substrate or superstrate. Additionally or alternatively hereto, it is however also possible to apply the curable precursor material on the surface of the substrate or of the superstrate. There are thereby possible as precursor materials all materials which can be cured for example chemically or thermally and hence form a permanent composite between solar cell and substrate or superstrate.

In the next step of the method, joining together of the faces of the solar cell and of the substrate and/or of the superstrate, which faces are wetted with the precursor material, is effected.

In a further step which can also be implemented before joining together or also at the same time, heating at least of the substrate and/or of the superstrate, possibly also of the solar cell, is effected, as a result of which it is ensured that greater absolute expansion of the substrate or of the superstrate results because of the higher thermal coefficients of expansion of the substrate or of the superstrate. After for example thermal curing of the precursor material, the resulting composite is cooled to ambient temperature, it being ensured that the forces occurring due to the thermal contraction during cooling are transmitted from the substrate and/or superstrate by means of the fixing to the solar cell. The solar cell is hence under permanent tangential pressure which emanates as a result of the greater absolute thermally-related change in size of the substrate or superstrate compared with the change in size of the solar cell.

The invention can hence be used advantageously for the production of wafer-based PV modules with particularly thin cells (<150 μm).

The invention enables the use of very thin cells (<150 μm) and cost savings on the cell side associated therewith. Furthermore, the thickness of the fixing material of currently approx. 500 μm can be significantly reduced (for example to 50 μm). Hence the operating temperature of the modules falls and the yield thereof increases.

It is a further advantage if modules are encapsulated via an accelerated method only at the edge side, for example with the material TPS, and no longer completely. The fixing according to the invention of the solar cells then already ensures securing of the cells in the gas-filled (disc) intermediate space.

In a preferred embodiment, the at least one precursor material is selected from the group consisting of organic materials which can be cured by cross-linking at the processing temperature and/or glass-like inorganic materials, in particular glass solder.

It is further preferred if the curable organic materials are selected from the group consisting of monomers, oligomers and/or prepolymers of duroplasts, in particular epoxy resins, phenol resins, (meth)acrylic resins and/or polyurethane resins.

In a further advantageous embodiment, there are used as substrate and/or superstrate glass materials with a linear coefficient of heat expansion a of at least 5·10⁻⁶/K at 20° C., preferably at least 6·10⁻⁶/K at 20° C., particularly preferred at least 7·10⁻⁶/K at 20° C.

It is likewise advantageous if a disc-shaped solar cell is used as solar cell.

Preferred thicknesses of the solar cell are thereby at <500 μm, preferably <300 μm, particularly preferred <150 μm.

It is likewise advantageous if the at least one precursor material forming the fixing is applied in a thickness of 5 to 500 μm, preferably of 10 to 100 μm, particularly preferred of 20 to 50 μm.

Preferred processing temperatures thereby extend from 90 to 600° C., preferably from 100 to 300° C., particularly preferred from 150 to 250° C.

According to the invention, a solar cell module is likewise provided, comprising at least one solar cell which is connected via a fixing at least in regions in a force- and form-fit to at least one substrate and/or superstrate, the thermal coefficient of expansion of the substrate and/or superstrate being greater than the thermal coefficient of expansion of the solar cell and the solar cell being under tangential pressure which emanates from the substrate and/or superstrate and is transmitted via the fixing to the solar cell in a temperature range below 100° C.

In particular, the solar cell module provided according to the invention has a fixing with a layer thickness of 5 to 500 μm, preferably of 10 to 100 μm, particularly preferred of 20 to 50 μm.

Furthermore, it is preferred if the solar cell module has an encapsulation which is applied on the solar cell and/or the superstrate on the rear-side, on which encapsulation a rear-side foil, a glass plate and/or a metal layer or -foil or -plate, preferably a rear-side foil, made of a fluorocarbon polymer, is disposed.

In an alternative preferred embodiment, the module has a rear-side foil which is applied on the solar cell and/or the superstrate on the rear-side, a glass plate and/or a metal layer, -foil or -plate which is connected to the superstrate and/or the solar cell merely in the edge region via a circumferential seal. Between the seal, the substrate or the solar cell and the rear-side covering, there is thereby produced a gas-filled space, the thickness of which corresponds to the layer thickness of the fixing. This gas space can be filled with any gases.

Preferably, the solar cell module according to the invention can be produced according to the previously mentioned method.

For better comprehension of the implementation of the present invention, the subject according to the invention is explained subsequently in more detail with reference to an embodiment and also a Figure.

The fixing is achieved by a material which has high strength without significant visco-elastic properties, for example duromers, polymers below the glass transition temperature or glass-like inorganic materials.

This fixing material is produced in such a manner that it cures at increased temperatures (for example >100° C., preferably >150° C.) of glass and solar cell, for example by cross-linking. During cooling of the produced composite, the solar cell is placed under tangential pressure as a result of the high thermal coefficient of expansion of glass. Because of the rigid connection to the glass, a pressure reserve is maintained for the lifespan of the module.

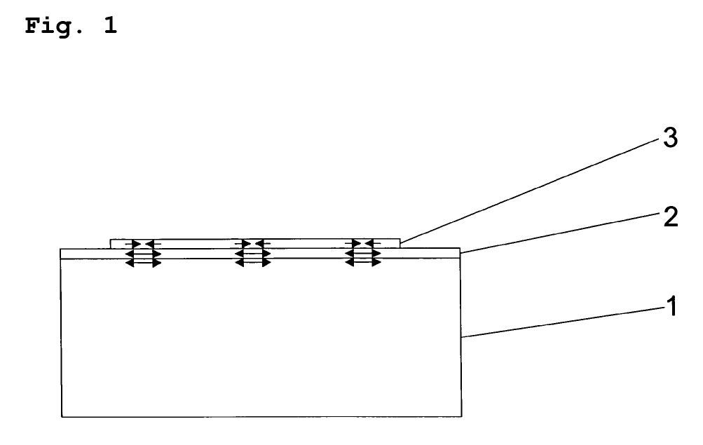

FIG. 1 shows the layer structure with the glass (superstrate) 1, fixing material 2 and cell 3. Under usage conditions of the module, the cell is predominantly under tangential pressure (arrows guided together), fixing material and glass are under tension (arrows moving away from each other).

During cooling to usage temperature, the composite is inclined to curve. This curvature can be reduced by designing the rear-side covering with an increased modulus of elasticity or by constructional absorption of the forces during the module assembly to the required degree.

The invention is suitable in particular for cells with rear contacts which have an essentially flat front-side.

1. A method for the production of a solar cell module, comprising the steps of:
a) applying a precursor material at least in regions on at least one of contact faces of a solar cell, a surface of a substrate and/or of a superstrate,
b) joining the contact faces together,
c) heating the substrate, the superstrate, the solar cell and/or the precursor material to a processing temperature of at least 90° C., steps a), b) and c) being implemented in any sequence,
d) curing the precursor material in order to fix the solar cell to the substrate and/or the superstrate, and
e) cooling the composite to ambient temperature,
wherein the thermal coefficient of expansion of the substrate and/or superstrate is greater than the thermal coefficient of expansion of the solar cell so that the solar cell is under tangential pressure permanently for the lifespan of the solar cell module, said pressure emanating from the substrate and/or superstrate and being transmitted to the solar cell via the fixing.

2. The method according to claim 1, wherein the at least one precursor material is selected from the group consisting of: organic materials which can be cured by cross-linking at the processing temperature, glass-like inorganic materials, and glass solder.

3. The method according to claim 2, wherein the curable organic materials are selected from the group consisting of: monomers, oligomers, prepolymers of duroplasts, epoxy resins, phenol resins, (meth)acrylate resins, and polyurethane resins.

4. The method according to claim 1, wherein there are used as substrate and/or superstrate glass materials with a linear coefficient of heat expansion α of: (i) at least 5·10⁻⁶/K at 20° C., (ii) at least 6·10⁻⁶/K at 20° C., or (iii) at least 7·10⁻⁶/K at 20° C.

5. The method according to claim 1, wherein a disc-shaped solar cell is used as the solar cell.

6. The method according to claim 1, wherein the thickness of the solar cell is: (i) <500 μm, (ii) <300 μm, or (iii) <150 μm.

7. The method according to claim 1, wherein the at least one precursor materials forming the fixing is applied in a thickness of: (i) 5 to 500 μm, (ii) 10 to 100 μm, or (iii) 20 to 50 μm.

8. The method according to claim 1, wherein the processing temperature is: (i) from 90 to 600° C., (ii) from 100 to 300° C., or (iii) from 150 to 250° C.

9. A solar cell module, comprising:
at least one solar cell which is connected via a fixing at least in regions in a force- and form-fit to at least one substrate and/or superstate,
wherein a thermal coefficient of expansion of the substrate and/or superstrate is greater than a thermal coefficient of expansion of the solar cell and the solar cell is under tangential pressure which emanates from the substrate and/or superstrate and is transmitted via the fixing to the solar cell in a temperature range below 100° C.

10. The solar cell module according to claim 9, wherein the fixing has a layer thickness of: (i) 5 to 500 μm, (ii) 10 to 100 μm, or (iii) 20 to 50 μm.

11. The solar cell module according to claim 9, further comprising an encapsulation which is applied on the solar cell and/or the superstrate on the rear-side, on which encapsulation a rear-side foil, a glass plate and/or a metal layer or -foil or -plate, preferably a rear-side foil made of a fluorocarbon polymer, is disposed.

12. The solar cell module according to claim 9, further comprising a rear-side foil which is applied on the solar cell and/or the superstrate on the rear-side, a glass plate and/or a metal layer, -foil or -plate which is connected to the solar cell and/or the superstrate in the edge region via a circumferential seal.

13. A solar cell module, comprising:
at least one solar cell which is connected via a fixing at least in regions in a force- and form-fit to at least one substrate and/or superstrate,
wherein the solar cell module is produced by way of steps, comprising:
a) applying a precursor material at least in regions on at least one of contact faces of the solar cell, a surface of the substrate and/or of the superstrate,
b) joining the contact faces together,
c) heating the substrate, the superstrate, the solar cell and/or the precursor material to a processing temperature of at least 90° C. steps a), b) and c) being implemented in any sequence,
d) curing the precursor material in order to fix the solar cell to the substrate and/or the superstrate, and
e) cooling the composite to ambient temperature,
wherein the thermal coefficient of expansion of the substrate and/or superstrate is greater than the thermal coefficient of expansion of the solar cell so that the solar cell is under tangential pressure permanently for the lifespan of the solar cell module, said pressure emanating from the substrate and/or superstrate and being transmitted to the solar cell via the fixing.
